(19) United States
(12) Patent Application Publication
(10) Pub. No.: US 2018/0024192 A1
(43) Pub. Date: Jan. 25, 2018

(54) TEST PATTERN COUNT REDUCTION FOR TESTING DELAY FAULTS

(71) Applicants: Arani SINHA, Hillsboro, OR (US); Sandip RAY, Beaverton, OR (US)

(72) Inventors: Arani SINHA, Hillsboro, OR (US); Sandip RAY, Beaverton, OR (US)

(21) Appl. No.: 15/721,511

(22) Filed: Sep. 29, 2017

Related U.S. Application Data
(63) Continuation-in-part of application No. 14/664,749, filed on Mar. 20, 2015.

(51) Int. Cl. G01R 31/317; G01R 31/3177

(52) U.S. Cl. CPC G01R 31/31703; G01R 31/3177

(57) ABSTRACT

One or more non-transitory computer-readable storage media is provided, the storage media is configured to store instructions that, when executed by a processor included in an apparatus, cause the processor to perform operations comprising: identify a plurality of transition faults that is to possibly occur in a circuit; generate a plurality of modified fault expressions, at least one of the plurality of modified fault expressions being associated with a corresponding transition fault of the plurality of transition faults; identify a plurality of test patterns, wherein at least one test pattern of the plurality of test patterns results in satisfiability of corresponding one or more of the plurality of modified fault expressions; and output the plurality of test patterns to a testing arrangement to test the circuit

### CLAIM OF PRIORITY

The present application is a continuation-in-part of and claims priority from U.S. patent application Ser. No. 14/664,749, filed Mar. 20, 2015, also published as United States Patent Publication Number 2016/0275224, and entitled “Apparatus and method for generating a reduced number of test vectors and inserting test points for a logic circuit,” which is herein incorporated by reference in its entirety.

### BACKGROUND

To test a circuit (e.g., a circuit within a semiconductor chip), a plurality of test vectors may be applied to the inputs of the circuit within the chip. The output of the chip may then be compared to an expected output of the chip. Inconsistencies between the actual output and the expected output may be compared, e.g., to detect possible errors in the actual output. Occurrence of such errors may result in the circuit being potentially recognized as faulty.

With an increase in size and complexity of logic design, a corresponding set of test vectors may become increasingly large. To detect some types of faults (e.g., delay faults), the set of test vectors may become even larger. Also, the larger the set of test vectors, the longer may be the testing time, testing cost, and testing complexity. It may be desirable to reduce the set of test vectors to test a given circuit.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a computing environment for testing a Device under Test (DUT) using a reduced set of test patterns for detecting transition faults, according to some embodiments.

FIG. 2A illustrates a circuit that may be tested in accordance with the embodiments of this disclosure.

FIG. 2B illustrates a faulty version of the circuit of FIG. 2A with a stuck-at-0 fault (or a slow to rise fault) at an output of an AND gate, according to some embodiments.

FIG. 2C illustrates an XOR operation of outputs of the circuits of FIGS. 2A and 2B, according to some embodiments.

FIG. 3 illustrates a flowchart depicting a method for generating test patterns for testing a DUT, according to some embodiments.

FIG. 4 illustrates a computer system or a SoC (System-on-Chip) to generate a reduced set of test patterns for detecting transition faults of a DUT, according to some embodiments.

### DETAILED DESCRIPTION

ATPG (e.g., acronym for both Automatic Test Pattern Generation and Automatic Test Pattern Generator) is an electronic design automation technology used to find an input (or test) sequence (also referred to as test patterns) that, when applied to a digital circuit under test, may enable automatic test equipment to distinguish between the correct circuit behavior and the faulty circuit behavior caused by defects. Generally, ATPG solutions may be based on branch-and-bound algorithms. For example, the ATPG procedure may target a fault, determine a test pattern that may detect the fault, and simulate the test pattern to determine all the faults that may be detected by the test pattern. The procedure may then remove the detected faults from the targeted set, and may iterate the process, e.g., until all faults may be detected. The procedure may also identify a group of faults as being untestable, e.g., faults that may not be detected because of the logic constraints required to detect them. This procedure, by design, may not have a means for targeting detection of a maximum number of faults per pattern (or a higher number of faults per pattern).

Generally, test patterns for delay tests (e.g., timing aware delay test) may be relatively high. For example, in timing aware delay test methodology, attempts may be made to find a test for a slow-to-rise or a slow-to-fall fault, e.g., such that the total delay of the path through which the fault is excited and propagated may be greater than a pre-determined value (e.g., greater than a pre-determined value of D). The pre-determined delay value D may be related to a critical path delay from Static Timing Analysis (STA). In an example, once a test pattern for a target delay based fault is found and is simulated, each of the additional faults that can be marked off as being detected by the test pattern may be required to exceed the delay value D on the path of excitation and propagation. Because of this criterion, a relatively few number of faults may be collaterally detected per test pattern.

Normally a circuit is scanned by replacing sequential elements such as latches and flip-flops by scan version of the elements. This may enhance the controllability and observability of the DUT. Each scan element may be a pseudo-primary input and output. In the following, when we refer to inputs or outputs, we refer to to the primary input and output of the design and/or to the pseudo-primary input and output, e.g., the scan elements.

Various embodiments of this disclosure are directed to algorithms based on MAXSAT-BAPA (Maximum Satisfiability-Boolean Algebra Presburger Arithmetic) formulation of the ATPG problem for test pattern count reduction and for enhanced testability. In some embodiments, one or more of the operations discussed herein applies the SMT (Satisfiability Modulo Theory) algorithm.

In some embodiments, the algorithms discussed herein may be directed to detecting delay faults, e.g., timing aware delay faults, cell aware delay faults, transition faults, path test delay faults, etc.

In some embodiments, the ATPG problem may be viewed as an instance of the well-known Satisfiability (SAT) problem. For example, test pattern for each fault may be written as a set of clauses, on literals for circuit nodes, in propositional calculus. The MAXSAT problem, by construction, may address satisfiability of maximum number of clauses simultaneously (e.g., in practice it may identify a maximal set). The MAXSAT formulation with BAPA may ensure that the delay value D is met for faults (e.g., for all faults) detected by the pattern. As a result, a relatively large number of faults may be detected per test pattern. This, in turn, may reduce the total set of test patterns to be used to test the circuit.

Other technical effects will be evident from the various embodiments and figures.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.” The terms “substantially,” “close,” “approximately,” “near,” and “about,” generally refer to being within +/−10% of a target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

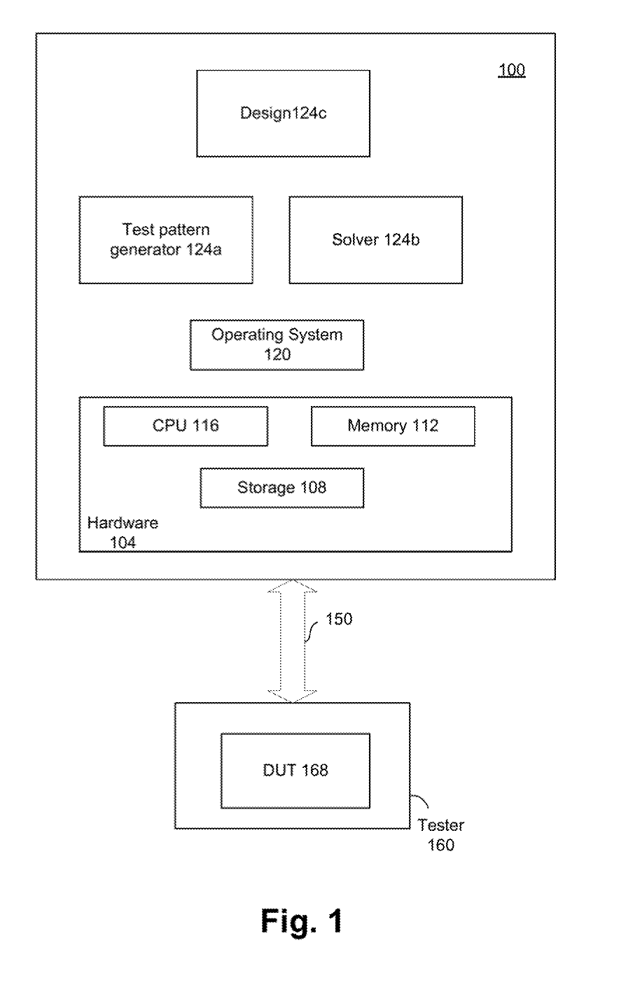

FIG. 1 illustrates a computing environment 100 for testing a Device under Test (DUT) 168 using a reduced set of test patterns for detecting transition faults, according to some embodiments. In some embodiments, the computing environment 100 may be implemented with a computer, e.g., a server or workstation computer.

In some embodiments, the computing environment 100 may comprise hardware computing platform 104. The hardware computing platform 101 may comprise a central processing unit (CPU) 116, memory 112 and storage 108. Although the hardware computing platform 101 is likely to include many other components (e.g., communication interface, peripheral connections, interconnect fabric, etc.), such components are not illustrated in FIG. 1 so as to not obfuscate the teachings of this disclosure.

In some embodiments, an operating system (OS) 120 may execute on the hardware platform 104. In some embodiments, one or more application software programs, such as test pattern generator 124a, solver 124b, etc. may also execute on the hardware platform 104. These application software programs are discussed later in further details. Although separate application software 124a, 124b, etc. are illustrated in FIG. 1, in some embodiments, these software programs may be integrated in a single software program.

In some embodiments, the test pattern generator 124a may have access to a design 124c of a device under test (DUT) 168. For example, if the DUT 168 is a circuit, the design 124c may include the design of the circuit, e.g., indicate various components of the DUT 168, such as logic gates, transistors, interconnections, etc. The design 124c may be stored using any appropriate programming language, e.g., a high-level description language (e.g., VHDL or Verilog) description, a register transfer language (RTL) description or netlist, a gate level netlist or a transistor level netlist, etc.

The software programs 124a and 124b may be program codes that may be written to effect the methodology of generating reduced count test patterns for transition testing, as discussed herein in this disclosure. In some embodiments, the solver 124b may comprise programs to solve MAXSAT-BAPA SMT problems. For example, the solver 124b may be an off-the-shelf or standardized program to solve MAXSAT-BAPA SMT problems, e.g., may be a MAXSAT-BAPA SMT solver or a MAXSAT solver. Such a solver 124b may be commercially available, or may be developed to solve standardized MAXSAT-BAPA SMT problems. The design of the methodology may be independent of the specifics of the underlying solver. Thus, the solver may be used as a black-box for the operations discussed herein. In some embodiments, the use of a SMT or a MAXSAT-BAPA SMT solver may provide a guarantee of local maximality of the solution achieved to the test-generation problem.

In some embodiments, the test pattern generator 124a may redefine the problem of generating test patterns into a corresponding MAXSAT problem (e.g., a MAXSAT-BAPA SMT problem). Subsequently, the test pattern generator 124a may make a function call to the solver 124b, e.g., to solve the MAXSAT problem. After the solver 124 generates a solution to the MAXSAT problem, the test pattern generator 124a may convert the solution to corresponding test patterns to test the DUT 168, and may transmit the resulting test patterns to a testing arrangement comprising tester 160. In some embodiments, the test pattern generator 124a may, at least temporarily, store the generated test patterns in the memory 112 and/or the storage 108.

In some embodiments, the computing environment 100 may be coupled to the tester 160, e.g., via a link 150, which may be a bi-directional communication link. The tester 160 may be, for example, a semiconductor chip tester.

The tester 160 may receive the DUT 168. The DUT 168 may be any appropriate device that may have to be tested, e.g., an integrated circuit chip. For example, the DUT 168 may be loaded into the tester 160. The tester 160 may receive test patterns from the computing environment 100 (e.g., from the test pattern generator 124a).

The tester 160 may test the DUT 168 by applying the input test patterns to the DUT 168, and generating corresponding output vectors. The tester 160 and/or the computing environment 100 may compare the generated output vectors with expected output vectors, e.g., to identify potential faults in the DUT 168.

Embodiments of the disclosure may include various processes as set forth in this disclosure. The processes may be embodied in machine-executable instructions. The instructions can be used to cause a general-purpose or special-purpose processor to perform certain processes. Alternatively, these processes may be performed by specific hardware components that contain hardwired logic for performing the processes, or by any combination of programmed computer components and custom hardware components.

Various elements of the disclosure may also be provided as a machine-readable medium for storing the machine-executable instructions. The machine-readable medium may include, but is not limited to, floppy diskettes, optical disks, CD-ROMs, and magneto-optical disks, FLASH memory, ROMs, RAMs, EPROMs, EEPROMs, magnetic or optical cards, propagation media or other type of media/machine-readable medium suitable for storing electronic instructions.

Various embodiments of this disclosure may also be implemented as an electronic circuit design such as an electronic circuit design expressed in any of high level description language (e.g., VHDL or Verilog) description, a register transfer language (RTL) description or netlist, a gate level netlist or a transistor level netlist. Although the above embodiments principally describe the design approach in relation to a gate level netlist, other embodiments may extend the teachings herein to other forms of circuit description.

Various embodiments of this disclosure discuss operation for generating test patterns in a digital circuit, e.g., to test timing delay faults. In some embodiments, one or more of the operations discussed herein applies the Maximal-SMT algorithm. Discussed herein are a formalization of timing-aware test-generation problem as a Max-SMT, and a methodology for discharging the SMT constraints through an off-the-shelf SMT solver (e.g., a commercially available solver).

Without loss of generality, a correct (e.g., a fault-free) functionality of a circuit C (e.g., a combinational circuit C) of m inputs and n outputs may be represented with a corresponding Boolean function F_{c}: {0, 1}^{m}→{0,1}ⁿ. Let ƒ[a] denote an a^{th} output of a Boolean function ƒ. A combinational circuit may be represented as a directed acyclic graph (DAG) of gates. The type of gates in a circuit may not be restricted, but it may be assumed that each gate g has a fixed gate delay D(g), which may be interpreted as follows. For a two-input AND gate with a gate delay of 10 nanoseconds (ns), if both inputs are available at time t, then the output may be available 10 ns after t, for example.

The four observations and definitions presented below are well-known results in theory of NP-completeness, Satisfiability, and Satisfiability-Modulo-Theories. These four observations are related to SAT, SMT, and/or MAXSAT:

Observation 1: Given a circuit C, it is possible to construct a Boolean formula ƒ(c), e.g., such that C and ƒ(c) computes the same function. Furthermore, if C is implemented with n number gates, then ƒ(C) may be implemented with O(n) gates, where O(.) is an appropriate function.

Observation 2. Any Boolean formula may be replaced by an equivalent formula Conjunctive Normal Form (CNF), e.g., with at most linear blow-up in size.

Observation 3. Let ƒ be a CNF formula which is represented by G₁ΛG₂Λ . . . ΛGₖ, e.g., such that each group G is itself a CNF formula. Then a Clausal MAXSAT may be to find a Boolean vector b such that the number of groups that evaluate to I is maximal.

Observation 4. Let ƒ be any Boolean formula in which the variables represent predicates for a specific theory T. Then satisfiability of the formula, taken as a predicate of T, may be computed by a composition of satisfiability checking and a solver for predicates in T. The procedure may be complete if the solver for T is complete.

A circuit C may have a stuck-at-zero fault at an wire or node w if, for example, instead of computing an output F_{c} (e.g., due to the stuck-at-zero fault), the circuit C computes another function F_{c,w0}: {0, 1}^{m}→{0, 1}ⁿ, where F_{c,w0} may be obtained by extending C with an additional input i_{w} directly connected to w, and assigning the Boolean value of 0 to i_{w}. Correspondingly, the circuit C may have a stuck-at-one fault at wire or node w if, for example, the circuit C computes the function F_{c,w1}: {0, 1}^{m}→{0, 1}ⁿ, where F_{c,w1} may be obtained by extending the circuit C with an additional input i_{w} directly connected to w, and assigning the Boolean value 1 to i_{w}. A stuck-at test is a Boolean vector of length m that may be provided as an input to the circuit C (e.g., during a testing of the circuit C). For detection of the stuck-at fault, the fault may be activated by exciting the opposite value at the fault site (0 for the stuck-at-1 fault, and 1 for the stuck-at-0 fault), and creating conditions on off-path inputs for propagating the fault to a circuit output.

A stuck-at test pattern b for the circuit C may be said to be “valid” for stuck-at-0 fault at wire or node w, if there exists an output o, such that F_{c}(b)[o]⊕F_{c,w0}(b)[o]=1. A stuck-at test pattern b for the circuit C may be said to be “valid” for stuck-at-1 fault at wire w, if there exists an output o, such that F_{c}(b)[o]⊕F_{c,w1}(b)[o]=1.

In an example, o(b,i)=1, e.g., if the i-th fault is detected by pattern b at output o.

A transition fault may occur in a sequential circuit at a wire or node w, when a transition from a first state to a second state is relatively slow (e.g., slower than expected, or slower than a threshold). For example, a slow transition from 0 to 1 may be referred to as a “slow-to-rise” transition fault. A slow transition from 1 to 0 may be referred to as a “slow-to-fall” transition fault. A transition fault may result in an incorrect value being latched or registered at a scan flop. Detecting a transition fault at any wire or node w may, thus, may require two phases: (1) an excitation phase to generate the fault at w, and (2) a propagation phase to propagate the fault from w to an output of the circuit. Consequently, a test for transition faults may be a sequence of two input vectors: a first input vector for excitation, and a second input vector that may contribute to both excitation and propagation.

The following may be a fact associated with Boolean function:

Fact 1: A computation of a sequential circuit C (e.g., a fault-free sequential circuit C) having m inputs and n outputs over two cycles may be represented by a Boolean function ƒₛ:{0,1}^{2m}→{0,1}²ⁿ, where the first m inputs may refer to the input values for the first cycle and the second m inputs may refer to the input values for the second cycle, and where the first n outputs may refer to the output values for the first cycle and the second n outputs may refer to the output values for the second cycle.

A test pattern b for a circuit C may be said to be “valid” for a stuck-at-0 fault at wire or node w, if there exists at least one output n, n=1, . . . . N, such that:

n(b,w0)=F_{c}(b)[n]⊕F_{c,w0}(b)[n]=1. Equation 1.

A test pattern b for a circuit C may be said to be “valid” for a stuck-at-1 fault at wire or node w, if there exists at least one output n, n=1, . . . , N such that:

n(b,w1)=F_{c}(b)/[n]⊕F_{c,w1}(b)[n]=1. Equation 2.

In equations 1 and 2, the number N may represent a number of outputs of a circuit under test, and “⊕” may represent an XOR operation.

Thus, if a fault is valid, then there may be a test pattern that can excite and test a fault. In an example, informally, test pattern b may allow to distinguish between the fault-free and faulty circuits, e.g., as the output of the fault-free circuit may be different from the faulty circuit on this input. Equivalently, it may be said that the test pattern b excites the stuck-at fault P at wire or node w.

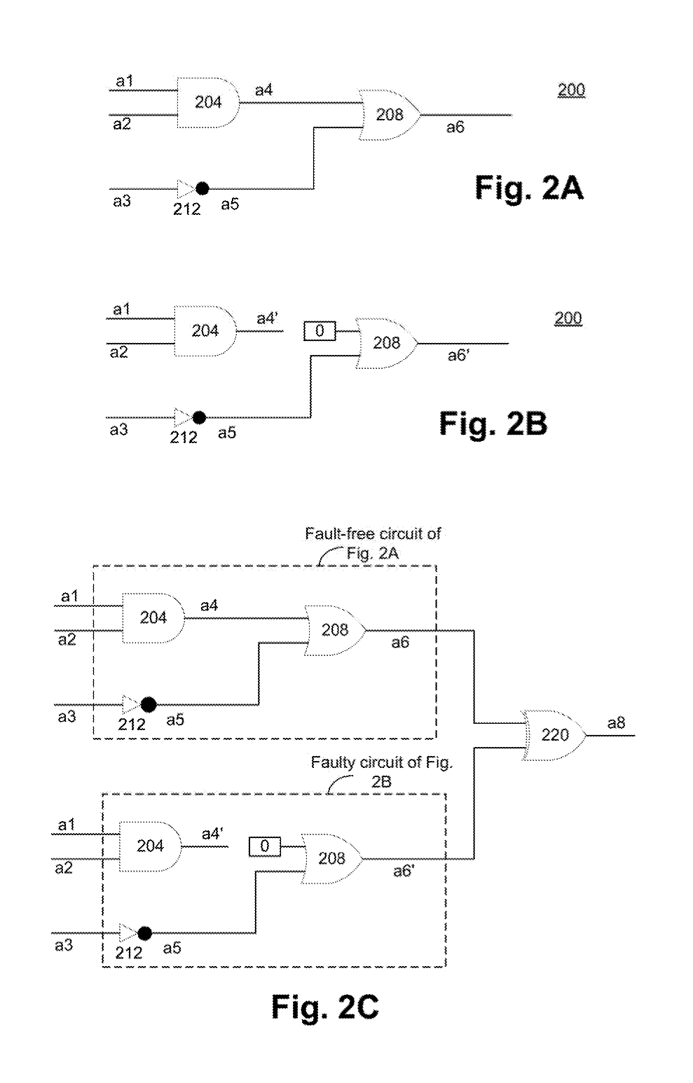

FIG. 2A illustrates a simple circuit 200 that may be tested in accordance with the embodiments of this disclosure. Although the circuit to be tested may be much more complex that the circuit 200, the circuit 200 is used to explain some of the concepts presented herein.

In some embodiments, the circuit 200 comprises the AND gate 204, the OR gate 208, the inverter 212, inputs a1, a2, a3, intermediate signals a4, a5, and output a6.

Assume that a test pattern is to be generated to detect a potential stuck-at-0 fault (or slow to rise fault) at the output of the AND gate 204. FIG. 2B illustrates a faulty version of the circuit 200 of FIG. 2A with a stuck-at-0 fault (or slow to rise fault) at the output of the AND gate 204. Thus, in FIG. 2B, irrespective of the value of the signal a4 (illustrated as a4′ in FIG. 2B), the input to the OR gate 208 is always 0.

For some values of the input {a1, a2, a3}, the outputs a6 and a′6 of the two circuits of FIGS. 2A and 2B, respectively, will be different. On the other hand, for some values of the input {a1, a2, a3}, the outputs a6 and a6′ will be the same. For example, if one or both a1 or a2 are zero, then the output a4 of the AND gate 204 is zero anyway, and such input values of a1 and a2 are said to not excite the fault. On the other hand, if both a1 and a2 are 1 and a3 is 1, then the outputs a6 and a6′ for the two scenarios of FIGS. 2A and 2B will be different.

In an example, the fault at the node or wire at the output of the AND gate 204 is said to be “valid” if there exists an input pattern for which the output a6 and a6′ are different. As discussed herein above, the fault in FIG. 2B is valid (e.g., the fault is detectable through monitoring the output a6).

FIG. 2C illustrates an XOR operation of the outputs of the circuits of FIGS. 2A and 2B, according to some embodiments. For example, the XOR operation of outputs a6 and a6′ is performed by the XOR gate 220 to generate the output a8. In the XOR operation, the output a8 is 1 if outputs a6 and a6′ are different. Also, note that the outputs a6 and a6′ are same for some values of the input vector {a1, a2, a3}, while the outputs a6 and a6′ are different for some other values of the input vector {a1, a2, a3}. Also, if the output a8 is 1 for a specific value of the input vector {a1, a2, a3}, then the specific value of the input vector {a1, a2, a3} (e.g., which may be {1, 1, 1}, merely as an example) is said to excite the fault at the output of the AND gate 204. This specific value of the input vector {a1, a2, a3} may be a valid test pattern b for the fault. The output of the circuit of FIG. 2C corresponds to the right side of equation 1. For this specific value of the input vector {a1, a2, a3}, the output a8 is one—that is, this specific value of the input vector {a1, a2, a3} satisfies equation 1 (e.g., evaluates the right side of equation 1 to the value of 1).

Thus, the circuit of FIG. 2C corresponds to the above discussed equation 1. For example, F_{c}(b)[n] in equation 1 represents the fault free circuit of FIG. 2A, the term F_{c,w0}(b)[n] represents the faulty circuit with a stuck-at-0 fault at a wire corresponding to the output of the AND gate 204, the operator ⊕ represents the XOR operation of XOR gate 220, and the output n is the output a6. Thus, equation 1 states that a test pattern b may be said to be valid if the output of the XOR operation is 1 (e.g., if the output a8 is 1). Thus, a valid test pattern b, for the example of FIGS. 2A-2C, may be {1, 1, 1}, which may excite the fault at the output of the AND gate 204.

Similar explanation may also be applicable for the equation 2 associated with a stuck-at-1 fault.

Various embodiments of this disclosure may define tests for delay faults. The following facts 2 and 3 may connect the test pattern generation to transition faults.

Fact 2: A computation of a sequential circuit C having m inputs and n outputs over two cycles may be represented by a Boolean function ƒₛ: {0,1}^{2m}→{0,1}²ⁿ, where the first m inputs (e.g., of the 2m inputs) may refer to the input values for the first cycle and the second m inputs (e.g., of the 2m inputs) may refer to the input values for the second cycle, and where the first n outputs (e.g., of the 2n outputs) may refer to the output values for the first cycle and the second n outputs (e.g., of the 2n outputs) refer to the output values for the second cycle.

The notion of Fact 2 may be extended to arbitrary internal signals as well. The notion of Fact 2 is standard and is also referred to as temporal unrolling of circuits. Variables corresponding to the first and second cycles may be referred to as unprimed and primed variables, respectively. For example, for a wire or node w, a value w may be used to represent its value in the first cycle, and w′ may be used to represent its value in the second cycle.

Fact 3: Excitation and propagation of a slow-to-rise transition at node or wire w is the same as (1) determining the assignment of unprimed variables that makes the value of computation at w to be 0, and (2) determining an assignment of primed variables to detect a stuck-at-0 fault at w.

In an example, Fact 3 may permit to extend the notion of stuck-at tests to transition faults. A test for a transition fault may be referred to as a delay-oblivious valid test (or as a valid test).

The following Theorems 1 and 2 may have proofs based on basic observations on SAT/SMT, and Facts 1 and 2 discussed above.

Theorem 1: For each transition fault g in a sequential circuit, there is a formula Q_{g}, representable in CNF, such that Q_{g} evaluates to 1 for each input that is a valid test for g.

Theorem 2: Let ƒ be a Boolean formula in CNF and G₁, . . . , G_{K} be an arbitrary grouping of conjuncts in ƒ. Then there exists a CNF formula ƒ′ (that includes all variables in f) containing k conjuncts C′₁, . . . , C′ₖ such that C′₁ is valid exactly for those input assignments to common variables of ƒ and ƒ′ for which Gᵢ is valid. This theorem may justify that Clausal MAXSAT can be reduced to MAXSAT. Now we turn to the connection between Clausal MAXSAT and generation of valid tests. Consider the formula P1 P2 . . . Pk, where Pi is the formula identified with the i-th fault as discussed in Theorem 1. Then by Fact 1, each Pi can be viewed as a group, as specified by Gi in the definition of Clausal MAXSAT. By definition of Clausal MAXSAT and Valid Test, a vector b that is a solution to Clausal MAXSAT is therefore a valid test that maximizes the number of faults covered.

Consider the formula P₁ [symbol] P₂ [symbol] . . . [symbol] Pᵢ . . . [symbol] P_{K}, where Pᵢ may be the formula identified with an i^{th} fault as discussed in Theorem 2, where K may be any appropriate number.

CNF fault expression of an i^{th} fault→Pᵢ. Equation 3.

Thus, a fault expression Pi defines a fault i. For example, assume that there are K/2 number of nodes in the circuit of the DUT 168. Each node can possibly have two transition faults: a slow to rise, and a slow to fall. Thus, there may be K number of possible faults in the circuit of the DUT 168. Note that this does not imply that there are actually K number of faults in the circuit—rather, this imply that there are K number of possibilities of transition faults in the circuit. The actual DUT 168 may have none, one, or more (e.g., up to K) number of transition faults. Thus, for each possible transition fault, a corresponding fault expression may be generated, e.g., such that fault expressions P₁, P₂, . . . , Pᵢ, . . . , P_{K} may be generated respectively for possible faults 1, 2, . . . , i, . . . , K.

In an example, a fault expression Pᵢ may correspond to the right side of one of equations 1 or 2. For example, for a 1^{st} fault, which may be a slow-to-rise fault, that occurs at node w, a corresponding fault expression P₁ may correspond to the right side of the equation 1. For example, for a 2^{nd} fault, which may be a slow-to-fall fault, that occurs at the node w, a corresponding fault expression P₂ may correspond to the left side of the equation 2.

As discussed herein later with respect to Algorithm 1, each fault expression Pᵢ, i=1, . . . , K. may be viewed as a group, as specified by Gᵢ in the definition of Clausal MAXSAT. By definition of Clausal MAXSAT and Valid Test, a vector b that is a solution to Clausal MAXSAT is therefore a valid test that maximizes the number of faults covered.

The notion of faults may be extended to gate delay awareness. Let g be a gate in a circuit C with inputs i₁, . . . , iₚ and output o. The gate g may be associated with an arrival time equation E(o), defined as:

E(o)=max(E(i₁), . . . ,E(iₚ))+D(g). Equation 4.

The term E(i₁) may represent an arrival time of an input i₁, the term E(iₚ) may represent an arrival time of an input iₚ, and so on. Thus, in equation 4, the term max(E(i₁), . . . . , E(iₚ)) represents an arrival time of a last input to arrive in the gate g. The term D(g) represents a gate delay at the gate g. Thus, the term E(o) represents an arrival time of the output o at the output of the gate g.

In an example, the arrival time equation E(o) may be a predicate, e.g., as E(o) may only take one of the values true or false. Consequently, the arrival time E(o) may be used in a condition (e.g., any condition) involving Boolean conjuncts. In an example, each input wire w may be associated with an equality E(w)=0. A conjunction of each delay equation in C may be referred to be the formula E(C). In an example, the arrival time equation may specify an amount of time (e.g., a delay) it may take for a value to propagate from an input of a circuit to a specific wire.

Proposition 1: Consider a formula P which is a conjunction of Pᵢ with (E(C) [symbol] ((∃_{On}, b ∃(_{On})>D [symbol] (_{On}(b,i)=1)) for some constant D. Then a satisfiable solution to P′₁ under linear arithmetic theory interpreting maximum is an input assignment that (1) is a valid test for the fault defined by Pᵢ, (2) satisfies all gate delays of circuit C, and (3) requires more than D units of time to propagate to a wire w.

Thus, the above discussed proposition 1 discusses the formula P′i, which is as follows:

P′ᵢ=P′ᵢ [symbol] (E(C) [symbol] ((∃_{On},b E(_{On})>D)) [symbol] (_{On}(b,i)=1)). Equation 5.

In equation 5, the term P′ᵢ may be referred to as a modified fault expression associated with the fault i. Thus, if there are K faults 1, 2, . . . , i, . . . . K, then there may be K number of modified fault expressions P′₁, P′₂, . . . , P′ᵢ, . . . , P′_{K}.

Referring again to equation 5, the CNF form of the fault expression P, has been discussed with respect to equation 3, the term _{On} represents an n^{th} output of the circuit C associated with the DUT 168, and the term “b” is a test pattern. The term E(C) may be a conjunction of each arrival time equations for the circuit C. The term “∃” represents a “there exists” clause. For example, the term (∃_{On},b E(_{On})>D) implies that there exists at least one output _{On} of the circuit C such that, with the i^{th} fault being assumed in the circuit C and for at least a test pattern b, the arrival time E(_{On}) is higher than a threshold delay D. Put differently, assume that the circuit C has the i^{th} fault (e.g., where i may be one of 1, 2, . . . , K, as discussed herein above), which may be a transition fault, e.g., a slow-to-rise fault or slow-to-fall fault. Thus, the term (∃_{On},b E(_{On})>D) checks that under the assumption of the i^{th} transition fault and for at least a test pattern b, whether the arrival time of at least one output (e.g., output _{On}) is delayed by more than the delay threshold D.

The term (_{On}(b,i)=1) is a predicate (e.g., may take a value of 1 or 0). For example, if the test pattern b manifests the fault effect at that output o(n), then the term (_{On}(b,i)=1) is 1; and else, the term is 0. Put differently, the term (_{On}(b,i)=1) in equation 5 may ensure that only a test pattern b, which may manifest the fault effect at the output o(n), may be considered.

In some embodiments, the term (∃_{On},b E(_{On})>D) may be a predicate—e.g., can take a value of 0 or 1. For example, if there exists at least one output for which the arrival time (e.g., under the assumption of the i^{th} fault) is more than the threshold delay D (assuming a test pattern b that may manifest at the output), than the term would have a value of 1; otherwise the term would have a value of 0.

In an example, the term (∃_{On},b E(_{On})>D) [symbol] (_{On}(b,i)=1), for an i^{th} fault, indicates whether at least one output is at an incorrect value for more than the threshold time period D, assuming that the i^{th} fault has occurred and assuming a test pattern b that manifests at the output. Note that the i^{th} fault is a transition fault (e.g., a slow-to-rise or slow-to-fall fault). Thus, the i^{th} fault may be present only for some time. For example, for a slow-to-rise fault, after some delay, the node will eventually rise, thereby eliminating the fault condition, and the outputs may transition eventually to the correct value. The term (∃_{On},b E(_{On})>D [symbol] (_{On}(b,i)=1)) may check as to whether at least one output, to which the fault effect has propagated, is in the incorrect value for sufficient amount of time for detection to take place. The term (∃_{On},b E(_{On})>D) may also be referred to herein as a detectability condition associated with a fault. For faults for which this term is one may be referred to as being detectable, and for faults for which this term is zero may be referred to as being undetectable.

Also, if (∃_{On},b E(o)>D) [symbol] (_{On}(b,i)=1) is one, then the conjunction operation of (E(C) [symbol] (∃_{On},b E(_{On})>D) [symbol] (_{On}(b,i)=1)) is 1. On the other hand, if (∃_{On},b E(_{On})>D) [symbol] (_{On}(b,i)=1) is zero, then the conjunction operation of (E(C) [symbol] (∃_{On},b E(_{On})>D) [symbol] (_{On}(b,i)=1)) is zero.

Thus, if (∃_{On},b E(_{On})>D [symbol] (_{On}(b,i)=1) is zero, then P′ᵢ is also zero, implying that the i^{th} fault cannot be detected (e.g., the fault is not valid). On the other hand, a non-zero value of the modified fault expression P′ᵢ implies that the fault is valid and can be detected by an appropriate test pattern (where the test pattern that can detect the fault can be determined by the solver 124b, as discussed with respect to algorithm 1 herein later). A non-zero modified fault expression is also referred to as detectable modified fault expression.

In some embodiments, the term (∃_{On},b E(_{On})>D [symbol] (_{On}(b,i)=1)) being 1 ensures that the there exists at least one output which, under the fault condition, is slow enough to change due to the fault, e.g., slow enough to be detected by the tester 160 of FIG. 1. Thus, in the modified fault expression P′ᵢ, the term Pi ensures that the i^{th} slow-to-rise or slow-to-fall fault is logically detectable, and the term (∃_{On},b E(_{On})>D) [symbol] (_{On}(b,i)=1) ensures that there is at least one output that is in the incorrect state long enough to be detected by the tester 160.

Thus, the modified fault expression P′ᵢ may be equal to either the fault expression Pᵢ or zero. That is, the modified fault expression P′ᵢ is derived from the fault expression Pᵢ, e.g., to ensure that the fault is detectable in at least one output of the circuit C of the DUT 168.

Theorem 3: Let a set SP′ be a set of two or more of modified fault expressions P′₁, P′₂, . . . , P′ᵢ, . . . , P′_{K} associated with the faults 1, 2, . . . , i, . . . , K. A MAXSAT solution for the set SP′ under interpretation of linear arithmetic theory interpreting maximum is a valid test for detecting a maximal subset of faults under the path constraints defined by delay equation.

In an example, a proof of Theorem 3 may follow from proposition 1, and a definition of MAXSAT and valid tests.

The following Theorem 4 may justify the use of an SMT approach for solving a question of valid tests through a standard SMT engine.

Theorem 4: The delay equations may be interpreted by a solver for theory of linear inequalities with SAT (e.g., Boolean Algebra Presburger Arithmetic or BAPA).

A proof of Theorem 4 may be as follows: noting that a finite maximum may be represented as an if-then-else clause, which may be represented by a multiplexor for the predicates.

In some embodiments, the following algorithm 1 may be used to construct a set of test patterns (e.g., a set of input vectors or test patterns for testing the DUT 168 of FIG. 1). For example, given a circuit C (e.g., corresponding to the DUT 168), the algorithm 1 may generate test patterns that may detect transition faults (e.g., slow-to-rise and/or slow-to-fall transition faults) at various wires of the circuit C. In some embodiments, given the circuit C, the algorithm 1 may generate test patterns that may detect transition faults at a maximal number of nodes (e.g., maximal number of wires) of the circuit C.

Algorithm 1:

Operation 1. Initialize a set of test patterns, e.g., set Test_patterns={ };

Operation 2. For a fault i, define a corresponding fault expression Pᵢ. For example, if there are possible K transition faults in the design 124c, define fault expressions P₁, P₂, . . . . Pᵢ, . . . , P_{K}.

Operation 3. For a fault i, define a corresponding modified fault expression P′ᵢ from the fault expression Pᵢ. For example, if there are K faults, define modified fault expressions P′₁, P′₂, . . . , P′ᵢ, . . . , P′_{K} corresponding to fault expressions P₁, P₂, . . . , Pᵢ, . . . , P_{K}. Construct a set SP′ of non-zero modified fault expressions, such that SP′={P′₂, . . . , P′ᵢ, . . . , P′_{K}}. (e.g., assuming that P′₁ is zero, and hence, is excluded from the set SP′).

Operation 4. Solve the Clausal MAXSAT problem using each P′ᵢ in the set SP′ as a group, by:
4a. Reducing the Clausal MAXSAT to MAXSAT based on Theorem 2.
4b. Using a solver (e.g., a MAXSAT-BAPA SMT solver, solver 124b, etc.) to solve the problem and possibly output a test pattern.

Operation 5. Perform one of the two following options:
5a. If the solver reports that none of the faults in current set SP′ is satisfiable, output the set Test_patterns and end algorithm.
5b. If the solver outputs a test pattern test_q during a q^{th} iteration of operations 4 and 5 and the test pattern test_q is associated with a q^{th} subset of the set SP′ of modified fault expressions, then (i) add test pattern test_q to the set Test_patterns and (ii) remove from the set SP′ of modified fault expressions the q^{th} subset of modified fault expressions. Also, if the set SP′ is now empty, output the set Test_patterns and end algorithm. Also, if the set SP′ is not empty, go to operation 4 to perform a (q+1)^{th} iteration of operations 4 and 5.

Referring to the operation 1 of algorithm 1, in some embodiments, a set of test patterns (e.g., the set “Test_patterns”) is initialized to zero (e.g., the set initially has not test patterns).

Referring to the operation 2 of algorithm 1, in some embodiments, the circuit C of the DUT 168 to be tested may have a plurality of nodes or wires. Each node can potentially have one of two transition faults: slow-to-rise transition fault or slow-to-fall transition fault. In some embodiments, if there are K/2 number of nodes, there may be K number of possible faults that may be desired to be tested. In operation 2, for each possible fault i, i=1, 2, . . . , K, a fault expression Pᵢ may be defined, e.g., as discussed with respect to equation 3. Thus, fault expressions P₁, P₂, . . . , Pᵢ, . . . , P_{K} may be defined.

Put differently, in the operation 2, the test pattern generator 124a (e.g., see FIG. 1) may analyze the design 124c of the circuit of the DUT 168, e.g., to detect transition faults that may possibly arise in the actual DUT 168. For example, the test pattern generator 124a may analyze, in the design of the circuit, all possible transition faults (e.g., all possible slow-to-rise and slow-to-rise faults) that may possibly occur in the DUT 168, and generated the fault expressions for the possible faults.

Referring to the operation 3 of algorithm 1, in some embodiments, modified fault expressions P′₁, P′₂, . . . , P′ᵢ, . . . , P′_{K} (e.g., corresponding to fault expressions P₁, P₂, . . . , Pᵢ, . . . , P_{K}, respectively) may be generated, e.g., as discussed with respect to equation 5. Note that some of the modified fault expressions (e.g., for which the term (∃_{On}, b E(_{On})>D) [symbol] (_{On}(b, i)=1) is zero) may be zero. Merely as an example, P′₁ is assumed to be zero (although in some other examples, this term may not be zero). In an example, the modified fault expressions, which are zero, may be referred to as undetectable fault expressions; and the modified fault expressions, which are non-zero, may be referred to as detectable fault expressions. Pi′ may be 0 at a given iteration but may become 1 at a later iteration.

Also, at operation 3, a set SP′ of non-zero modified fault expressions are generated, such that SP′={P′₂, . . . , P′ᵢ, . . . , P′_{K}}. Note that if a modified fault expression is zero, the modified fault expression may be excluded from the set SP′. Merely as an example, P′₁ is assumed to be zero and is excluded from the set SP′. As discussed, the modified fault expressions may be in the CNF forms.

As discussed with respect to equation 5, a modified fault expression P′ᵢ may be equal to either the corresponding fault expression Pᵢ or zero. That is, the modified fault expression P′ᵢ is derived from the fault expression Pᵢ, e.g., to ensure that the fault is detectable in at least one output of the circuit C of the DUT 168. Thus, in operation 3, the set SP′ essentially is a collection of one or more of the fault expressions P₁, P₂, . . . . Pᵢ, . . . , P_{K} that may be detectable at the output (e.g., at least one output is at the incorrect value long enough to be detected). The pruning of some of the fault expressions is achieved by generating the modified fault expressions, and ensuring that only those modified fault expression, which have the corresponding expression (∃_{On},b E(_{On})>D) [symbol] (_{On}(b,i)=1) as one, is included in the set SP′.

Referring to the operation 4 of algorithm 1, the clausal MAXSAT problem for each modified fault expression in the set SP′ is solved as a group. Merely as an example, assume there are 12 number of possible faults in the DUT 168 (although, in real DUTs, the number would be much larger). Thus, K=12, and the fault expressions of operation 2 are P₁, . . . , P₁₂. Also, the modified fault expressions of operation 3 are P′₁, . . . , P′₁₂. Let P′₁ is zero and is excluded from the set SP′. Thus, the set SP′ at the first iteration of operation 3 is (P′₂, . . . , P′₁₂).

Now, the solver solves the MAXSAT-BAPA SMT problem as follows. Assume, merely as an example, that there is a test pattern b1 for which P′₂=1 and P′₄=1. That is, the test pattern b1 is a valid test pattern for two modified fault expressions P′₂ and P′₄. Also, assume test pattern b2 is a valid test pattern for four modified fault expressions P′₂, P′₈, P′₁₀, and P′₁₂. Also, assume test pattern b3 is a valid test pattern for one modified fault expression P′₃. Thus, in this example, the test pattern b2 is a valid test pattern for most number of modified fault expressions. Note that as discussed in Theorem 5 herein later, the MAXSAT-BAPA SMT can identify the test pattern (e.g., at each iteration) that can have a maximal coverage of the faults. For example, if the maximum number of faults that can be covered by a test pattern in the set SP′ is three, then the solver 124b is bound to find this test pattern, which is test pattern b2 in the above example. Thus, if a test pattern is valid for at least one modified fault expression, then at least one of the modified fault expressions in the set SP′ is said to be satisfiable.

In the above example, as there exists the test pattern b2 that is satisfiable, the operation 5b may be executed. For example, during the 1^{st} iteration of operations 4 and 5 (e.g., q=1 in algorithm 1), the test pattern b2 is associated with 1^{st} subset {P′₂, P′₈, P′₁₀, and P′₁₂} of the set SP′ of modified fault expressions. Accordingly, the test pattern b2 is added to the set Test_patterns, and the 1^{st} subset {P′₂, P′₈, P′₁₀, P′₁₂} is removed from the set SP′. Thus, the set SP′ is now reduced to {P′₃, P′₄, P′₅, P′₆, P′₇, P′₉, P′₁₁}. As the set SP′ is not empty, the execution of the algorithm 1 goes to operation 4 again for a 2^{nd} iteration.

The iterations of operations 4 and 5 continues until, for example, one of the conditions in specified in operations 5a or 5b is satisfied. Based on satisfaction of such an “end” clause, the algorithm 1 ends and the set Test_patterns is output by the test pattern generator 124a.

For example, after the execution of the algorithm 1, the test pattern generator 124a transmits the set Test_patterns to the tester, e.g., for testing the DUT 168.

Theorem 5: At each iteration of the operations 4 and 5 of algorithm 1, the set of faults covered is maximal. That is, no other test pattern can cover a superset of the faults remaining at any iteration.

Proof: Follows from the definition of MAXSAT and the fact that BAPA is a complete theory of linear arithmetic.

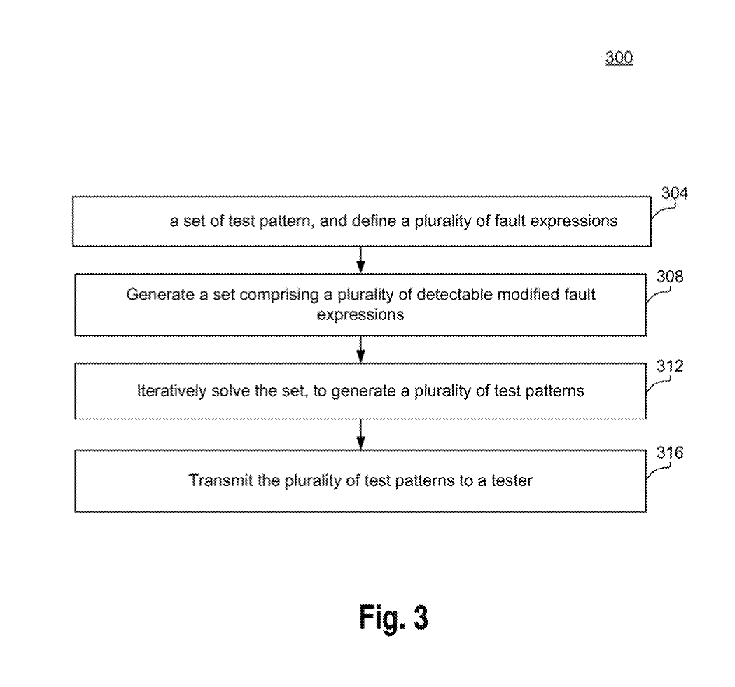

FIG. 3 illustrates a flowchart depicting a method 300 for generating test patterns for testing a DUT (e.g., DUT 168 of FIG. 1), according to some embodiments. Although the blocks in the flowchart with reference to FIG. 3 are shown in a particular order, the order of the actions can be modified. Thus, the illustrated embodiments can be performed in a different order, and some actions/blocks may be performed in parallel. Some of the blocks and/or operations listed in FIG. 3 may be optional in accordance with certain embodiments. The numbering of the blocks presented is for the sake of clarity and is not intended to prescribe an order of operations in which the various blocks must occur.

In some embodiments, at 304 of the method 300, a set of test pattern is initialized (e.g., by the test pattern generator 124a and as discussed with respect to operation 1 of algorithm 1). Also at 304, a plurality of fault expressions (e.g., P₁, P₂, . . . , Pᵢ, . . . , P_{K}) is defined (e.g., by the test pattern generator 124a and as discussed with respect to operation 2 of algorithm 1).

At 308, a set comprising a plurality of detectable modified fault expressions is generated (e.g., the set SP′={P′₂, . . . , P′ᵢ, . . . , P′_{K}}, as discussed with respect to operation 3 of algorithm 1. In some embodiments, a detectable modified fault expression is a fault expression that is non-zero, as discussed with respect to equation 5.

At 312, the set may be iteratively solved using a solver (e.g., solver 124b of FIG. 1), to generate a plurality of test patterns, as discussed with respect to operations 4 and 5 of algorithm 1. At 316, the plurality of test patterns is transmitted to a tester (e.g., tester 160) to test the DUT 168.

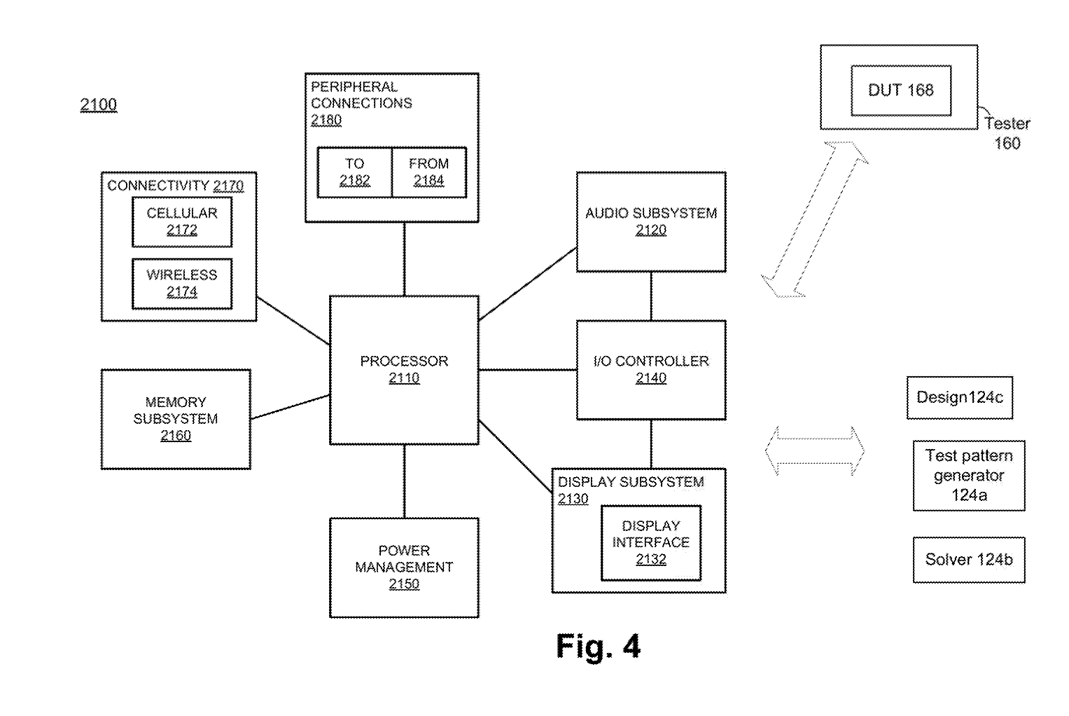

FIG. 4 illustrates a computer system or a SoC (System-on-Chip) 2100 to generate a reduced set of test patterns for detecting transition faults of a DUT, according to some embodiments. It is pointed out that those elements of FIG. 4 having the same reference numbers (or names) as the elements of any other figure can operate or function in any manner similar to that described, but are not limited to such.

In some embodiments, computing device 2100 represents an appropriate computing device, such as a computing tablet, a mobile phone or smart-phone, a laptop, a desktop, an IOT device, a server, a set-top box, a wireless-enabled e-reader, or the like. It will be understood that certain components are shown generally, and not all components of such a device are shown in computing device 2100.

In some embodiments, computing device 2100 includes a first processor 2110. The various embodiments of the present disclosure may also comprise a network interface within 2170 such as a wireless interface so that a system embodiment may be incorporated into a wireless device, for example, cell phone or personal digital assistant.

In one embodiment, processor 2110 can include one or more physical devices, such as microprocessors, application processors, microcontrollers, programmable logic devices, or other processing means. The processing operations performed by processor 2110 include the execution of an operating platform or operating system on which applications and/or device functions are executed. The processing operations include operations related to I/O with a human user or with other devices, operations related to power management, and/or operations related to connecting the computing device 2100 to another device. The processing operations may also include operations related to audio I/O and/or display I/O.

In one embodiment, computing device 2100 includes audio subsystem 2120, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 2100, or connected to the computing device 2100. In one embodiment, a user interacts with the computing device 2100 by providing audio commands that are received and processed by processor 2110.

Display subsystem 2130 represents hardware (e.g., display devices) and software (e.g., drivers) components that provide a visual and/or tactile display for a user to interact with the computing device 2100. Display subsystem 2130 includes display interface 2132, which includes the particular screen or hardware device used to provide a display to a user. In one embodiment, display interface 2132 includes logic separate from processor 2110 to perform at least some processing related to the display. In one embodiment, display subsystem 2130 includes a touch screen (or touch pad) device that provides both output and input to a user.

I/O controller 2140 represents hardware devices and software components related to interaction with a user. I/O controller 2140 is operable to manage hardware that is part of audio subsystem 2120 and/or display subsystem 2130. Additionally, I/O controller 2140 illustrates a connection point for additional devices that connect to computing device 2100 through which a user might interact with the system. For example, devices that can be attached to the computing device 2100 might include microphone devices, speaker or stereo systems, video systems or other display devices, keyboard or keypad devices, or other I/O devices for use with specific applications such as card readers or other devices.

As mentioned above, I/O controller 2140 can interact with audio subsystem 2120 and/or display subsystem 2130. For example, input through a microphone or other audio device can provide input or commands for one or more applications or functions of the computing device 2100. Additionally, audio output can be provided instead of, or in addition to display output. In another example, if display subsystem 2130 includes a touch screen, the display device also acts as an input device, which can be at least partially managed by I/O controller 2140. There can also be additional buttons or switches on the computing device 2100 to provide I/O functions managed by I/O controller 2140.

In one embodiment, I/O controller 2140 manages devices such as accelerometers, cameras, light sensors or other environmental sensors, or other hardware that can be included in the computing device 2100. The input can be part of direct user interaction, as well as providing environmental input to the system to influence its operations (such as filtering for noise, adjusting displays for brightness detection, applying a flash for a camera, or other features).

In one embodiment, computing device 2100 includes power management 2150 that manages battery power usage, charging of the battery, and features related to power saving operation. Memory subsystem 2160 includes memory devices for storing information in computing device 2100. Memory can include nonvolatile (state does not change if power to the memory device is interrupted) and/or volatile (state is indeterminate if power to the memory device is interrupted) memory devices. Memory subsystem 2160 can store application data, user data, music, photos, documents, or other data, as well as system data (whether long-term or temporary) related to the execution of the applications and functions of the computing device 2100. In one embodiment, computing device 2100 includes a clock generation subsystem 2152 to generate a clock signal.

Elements of embodiments are also provided as a machine-readable medium (e.g., memory 2160) for storing the computer-executable instructions (e.g., instructions to implement any other processes discussed herein). The machine-readable medium (e.g., memory 2160) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 2170 includes hardware devices (e.g., wireless and/or wired connectors and communication hardware) and software components (e.g., drivers, protocol stacks) to enable the computing device 2100 to communicate with external devices. The computing device 2100 could be separate devices, such as other computing devices, wireless access points or base stations, as well as peripherals such as headsets, printers, or other devices.

Connectivity 2170 can include multiple different types of connectivity. To generalize, the computing device 2100 is illustrated with cellular connectivity 2172 and wireless connectivity 2174. Cellular connectivity 2172 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 2174 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 2180 include hardware interfaces and connectors, as well as software components (e.g., drivers, protocol stacks) to make peripheral connections. It will be understood that the computing device 2100 could both be a peripheral device (“to” 2182) to other computing devices, as well as have peripheral devices (“from” 2184) connected to it. The computing device 2100 commonly has a “docking” connector to connect to other computing devices for purposes such as managing (e.g., downloading and/or uploading, changing, synchronizing) content on computing device 2100. Additionally, a docking connector can allow computing device 2100 to connect to certain peripherals that allow the computing device 2100 to control content output, for example, to audiovisual or other systems.

In addition to a proprietary docking connector or other proprietary connection hardware, the computing device 2100 can make peripheral connections 2180 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

In some embodiments, the computing device 2100 may be implement the computing environment 100 of FIG. 1. In some embodiments, the computing device 2100 may store and execute software applications such as the test pattern generator 124a and the solver 124b, as discussed with respect to FIG. 1. In some embodiments, the computing device 2100 may store the design 124c, as discussed with respect to FIG. 1. In some embodiments, the computing device 2100 may be coupled to the tester 160 comprising the DUT 168. In some embodiments, the computing device 2100 may generate test patterns and transmit the test patterns to the tester 160 for testing the DUT 168, as discussed in this disclosure.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following example clauses pertain to further embodiments. Specifics in the example clauses may be used anywhere in one or more embodiments. All optional features of the apparatus described herein may also be implemented with respect to a method or process.

### Example 1

One or more non-transitory computer-readable storage media configured to store instructions that, when executed by a processor included in an apparatus, cause the processor to perform operations comprising: identify a plurality of transition faults that is to possibly occur in a circuit; generate a plurality of modified fault expressions, at least one of the plurality of modified fault expressions being associated with a corresponding transition fault of the plurality of transition faults; identify a plurality of test patterns, wherein at least one of the plurality of test patterns is to result in satisfiability of corresponding one or more of the plurality of modified fault expressions; and output the plurality of test patterns to a testing arrangement to test the circuit.

### Example 2

The one or more non-transitory computer-readable storage media of example 1 or any other example, wherein: a test pattern is to result in satisfiability of a modified fault expression if, for the test pattern, the modified fault expression is to evaluate to a logical one value.

### Example 3

The one or more non-transitory computer-readable storage media of example 1 or any other example, wherein: the plurality of transition faults comprises one or more slow-to-rise faults and one or more slow-to-fall faults.

### Example 4

The one or more non-transitory computer-readable storage media of example 1 or any other example, wherein: the plurality of transition faults comprises a corresponding slow-to-rise fault and a corresponding slow-to-fall fault at a corresponding node of a plurality of nodes of the circuit.

### Example 5

The one or more non-transitory computer-readable storage media of any of examples 1-4 or any other example, wherein to identify the plurality of test patterns, the processor is to perform operations comprising: iteratively identify, using a MAXSAT-BAPA SMT (Maximum Satisfiability-Boolean Algebra Presburger Arithmetic-Satisfiability Modulo Theory) solver, the plurality of test patterns.

### Example 6

The one or more non-transitory computer-readable storage media of any of examples 1-4 or any other example, wherein to identify the plurality of test patterns, the processor is to perform operations comprising: generate a set comprising the plurality of modified fault expressions; identify, during a first iteration, a first test pattern that satisfies a first number of modified fault expressions of the set; and update the set by removing the first number of modified fault expressions from the set.

### Example 7

The one or more non-transitory computer-readable storage media of example 6 or any other example, wherein to identify the plurality of test patterns, the processor is to perform operations comprising: identify, during a second iteration, a second test pattern that satisfies a second number of modified fault expressions of the updated set; further update the set by removing the second number of modified fault expressions from the updated set; and identify the plurality of test patterns such that the plurality of test patterns includes at least the first test pattern and the second test pattern.

### Example 8

The one or more non-transitory computer-readable storage media of any of examples 1-4 or any other example, wherein to generate the plurality of modified fault expressions, the processor is to perform operations comprising: generate a first fault expression and a second fault expression corresponding to a first fault and a second fault, respectively; determine that there exists in the circuit at least an output whose value is to remain incorrect for at least a threshold period of time, if the first fault is assumed to occur, determine that there does not exist in the circuit any output whose value is to remain incorrect for at least the threshold period of time, if the second fault is assumed to occur; generate, for the first fault, a first modified fault expression to be equal to the first fault expression; generate, for the second fault, a second modified fault expression to be equal to zero; and generate the plurality of modified fault expressions to include the first modified fault expression and exclude the second modified fault expression.

### Example 9

A system comprising: a testing arrangement to receive a Device Under Test (DUT), and to test the DUT; and a computing environment coupled to the testing arrangement, the computing environment comprising: a memory to store instructions; and a processor coupled to the memory, the processor to: identify a plurality of transition faults that is to possibly occur in the DUT; generate a set comprising a plurality of modified fault expressions, at least one of the plurality of modified fault expressions being associated with a corresponding transition fault of the plurality of transition faults; identify, during a first iteration, a first test pattern that is to satisfy a first number of modified fault expressions of the set; and update the set, by removing the first number of modified fault expressions from the set, to generate a first updated set.

### Example 10

The system of example 9 or any other example, wherein the processor is to: identify, during a second iteration, a second test pattern that is to satisfy a second number of modified fault expressions of the first updated set; and update the first updated set, by removing the second number of modified fault expressions, to generate a second update set.

### Example 11

The system of example 10 or any other example, wherein the processor is to: fail to identify, during a third iteration, any test pattern that satisfies any modified fault expression of the second updated set, and generate a set of test patterns, the set of test patterns comprising the first test pattern and the second test pattern.

### Example 12

The system of example 11 or any other example, wherein the processor is to: transmit the set of test patterns to the testing arrangement.

### Example 13

The system of example 11 or any other example, wherein the processor is to fail to identify, during the third iteration, any test pattern that satisfies any modified fault expression of the second updated set, as the second updated set is an empty set.

### Example 14

The system of example 10 or any other example, wherein during the second iteration, the second test pattern satisfies a maximal number of modified fault expressions of the first updated set.

### Example 15

The system of any of examples 9-14 or any other example, wherein to identify, during the first iteration, the first test pattern, the processor is to: identify the first test pattern using a MAXSAT (Maximum Satisfiability) solver.

### Example 16

The system of any of examples 9-14 or any other example, wherein to identify, during the first iteration, the first test pattern, the processor is to: identify that for the first test pattern, individual ones of the first number of modified fault expressions of the set is to evaluate to a logical one value.

### Example 17

The system of any of examples 9-14 or any other example, wherein the plurality of transition faults comprises: a corresponding slow-to-rise fault and a corresponding slow-to-fall fault at a corresponding node of a plurality of nodes of the DUT.

### Example 18

A method comprising: identifying a plurality of transition faults that can possibly occur in a circuit; generating a plurality of fault expressions respectively corresponding to the plurality of transition faults; selecting a first subset of the fault expressions from the plurality of fault expressions, such that for at least one fault expression in the first subset, there exists at least one corresponding output of the circuit that is at an incorrect state for more than a threshold period of time, if the corresponding transition fault is to occur; and generating a plurality of test patterns for testing the circuit, based at least in part on the first subset of fault expressions.

### Example 19

The method of example 18 or any other example, further comprising: determining that for each fault expression in a second subset of fault expressions, there does not exist any corresponding output of the circuit that is at an incorrect state for more than the threshold period of time, if the corresponding transition fault is to occur, and excluding, from the first subset of fault expressions, any fault expression of the second subset of fault expressions.

### Example 20

The method of any of examples 18-19 or any other example, wherein generating the plurality of test patterns comprises: generating the plurality of test patterns using a MAXSAT (Maximum Satisfiability) solver.

### Example 21

An apparatus comprising: a memory to store instructions; and a processor coupled to the memory, the processor to perform operations comprising: identify a plurality of transition faults that can possibly occur in a Device Under Test (DUT); generate a plurality of fault expressions respectively corresponding to the plurality of transition faults; select a first subset of the fault expressions from the plurality of fault expressions, such that for at least one fault expression in the first subset, there exists at least one corresponding output of the DUT that is at an incorrect state for more than a threshold period of time, if the corresponding transition fault is to occur; generate a plurality of test patterns for testing the DUT, based at least in part on the first subset of fault expressions; and transmit the plurality of test patterns to a tester for testing the DUT

### Example 22

The apparatus of example 21 or any other example, wherein the processor is to perform operations comprising: determine that for each fault expression in a second subset of fault expressions, there does not exist any corresponding output of the DUT that is at an incorrect state for more than the threshold period of time, if the corresponding transition fault is to occur; and exclude, from the first subset of fault expressions, any fault expression of the second subset of fault expressions.

### Example 23

The apparatus of any of examples 21-22 or any other example, wherein the processor to perform operations comprising: generate the plurality of test patterns using a MAXSAT (Maximum Satisfiability) solver.

### Example 24

The apparatus of any of examples 21-22 or any other example, further comprising: a communicating link to interface with the tester.

### Example 25

The apparatus of any of examples 21-22 or any other example, wherein the processor is to perform operations comprising: iteratively generate the plurality of test patterns for testing the DUT, such that the plurality of test patterns is a minimal number of test patterns that can test the plurality of transition faults.

### Example 26

A method comprising: identifying a plurality of transition faults that is to possibly occur in a circuit; generating a plurality of modified fault expressions, at least one of the plurality of modified fault expressions being associated with a corresponding transition fault of the plurality of transition faults; identifying a plurality of test patterns, wherein at least one of the plurality of test patterns is to result in satisfiability of corresponding one or more of the plurality of modified fault expressions; and outputting the plurality of test patterns to a testing arrangement to test the circuit.

### Example 27

The method of example 26 or any other example, wherein: a test pattern is to result in satisfiability of a modified fault expression if, for the test pattern, the modified fault expression is to evaluate to a logical one value.

### Example 28

The method of example 26 or any other example, wherein: the plurality of transition faults comprises one or more slow-to-rise faults and one or more slow-to-fall faults.

### Example 29

The method of example 26 or any other example, wherein: the plurality of transition faults comprises a corresponding slow-to-rise fault and a corresponding slow-to-fall fault at a corresponding node of a plurality of nodes of the circuit.

### Example 30

The method of any of examples 26-29 or any other example, identifying the plurality of test patterns comprises: iteratively identifying, using a MAXSAT-BAPA SMT (Maximum Satisfiability-Boolean Algebra Presburger Arithmetic-Satisfiability Modulo Theory) solver, the plurality of test patterns.

### Example 31

The method of any of examples 26-29 or any other example, wherein identifying the plurality of test patterns comprises: generating a set comprising the plurality of modified fault expressions; identifying, during a first iteration, a first test pattern that satisfies a first number of modified fault expressions of the set; and updating the set by removing the first number of modified fault expressions from the set.

### Example 32

The method of example 31 or any other example, wherein identifying the plurality of test patterns comprises: identifying, during a second iteration, a second test pattern that satisfies a second number of modified fault expressions of the updated set; further updating the set by removing the second number of modified fault expressions from the updated set; and identifying the plurality of test patterns such that the plurality of test patterns includes at least the first test pattern and the second test pattern.

### Example 33

The method of any of examples 26-29 or any other example, wherein generating the plurality of modified fault expressions comprises: generating a first fault expression and a second fault expression corresponding to a first fault and a second fault, respectively; determining that there exists in the circuit at least an output whose value is to remain incorrect for at least a threshold period of time, if the first fault is assumed to occur; determining that there does not exist in the circuit any output whose value is to remain incorrect for at least the threshold period of time, if the second fault is assumed to occur; generating, for the first fault, a first modified fault expression to be equal to the first fault expression; generating, for the second fault, a second modified fault expression to be equal to zero; and generating the plurality of modified fault expressions to include the first modified fault expression and exclude the second modified fault expression.

### Example 34

One or more non-transitory computer-readable storage media to store instructions that, when executed by a processor, cause the processor to execute a method of any of the examples 18-20 and 26-33 or any other example.

### Example 35

An apparatus comprising: means for performing the method of any of the examples 18-20 and 26-33 or any other example.

### Example 36

An apparatus comprising: means for identifying a plurality of transition faults that can possibly occur in a circuit; means for generating a plurality of fault expressions respectively corresponding to the plurality of transition faults; means for selecting a first subset of the fault expressions from the plurality of fault expressions, such that for at least one fault expression in the first subset, there exists at least one corresponding output of the circuit that is at an incorrect state for more than a threshold period of time, if the corresponding transition fault is to occur, and means for generating a plurality of test patterns for testing the circuit, based at least in part on the first subset of fault expressions.

### Example 37

The apparatus of example 36 or any other example, further comprising: means for determining that for each fault expression in a second subset of fault expressions, there does not exist any corresponding output of the circuit that is at an incorrect state for more than the threshold period of time, if the corresponding transition fault is to occur, and means for excluding, from the first subset of fault expressions, any fault expression of the second subset of fault expressions.

### Example 38

The apparatus of any of examples 36-37 or any other example, wherein the means for generating the plurality of test patterns comprises: means for generating the plurality of test patterns using a MAXSAT (Maximum Satisfiability) solver.

### Example 38

An apparatus comprising: means for identifying a plurality of transition faults that is to possibly occur in a circuit; means for generating a plurality of modified fault expressions, at least one of the plurality of modified fault expressions being associated with a corresponding transition fault of the plurality of transition faults; means for identifying a plurality of test patterns, wherein at least one of the plurality of test patterns is to result in satisfiability of corresponding one or more of the plurality of modified fault expressions; and means for outputting the plurality of test patterns to a testing arrangement to test the circuit.

### Example 39

The apparatus of example 38 or any other example, wherein: a test pattern is to result in satisfiability of a modified fault expression if, for the test pattern, the modified fault expression is to evaluate to a logical one value.

### Example 40

The apparatus of example 38 or any other example, wherein: the plurality of transition faults comprises one or more slow-to-rise faults and one or more slow-to-fall faults.

### Example 41

The apparatus of example 38 or any other example, wherein: the plurality of transition faults comprises a corresponding slow-to-rise fault and a corresponding slow-to-fall fault at a corresponding node of a plurality of nodes of the circuit.

### Example 42

The apparatus of any of examples 38-41 or any other example, wherein the means for identifying the plurality of test patterns comprises: means for iteratively identifying, using a MAXSAT-BAPA SMT (Maximum Satisfiability-Boolean Algebra Presburger Arithmetic-Satisfiability Modulo Theory) solver, the plurality of test patterns.

### Example 43

The apparatus of any of examples 38-41 or any other example, wherein the means for identifying the plurality of test patterns comprises: means for generating a set comprising the plurality of modified fault expressions; means for identifying, during a first iteration, a first test pattern that satisfies a first number of modified fault expressions of the set; and means for updating the set by removing the first number of modified fault expressions from the set.

### Example 44

The apparatus of example 43 or any other example, wherein the means for identifying the plurality of test patterns comprises: means for identifying, during a second iteration, a second test pattern that satisfies a second number of modified fault expressions of the updated set; means for further updating the set by removing the second number of modified fault expressions from the updated set; and means for identifying the plurality of test patterns such that the plurality of test patterns includes at least the first test pattern and the second test pattern.

### Example 45

The apparatus of any of examples 38-41 or any other example, wherein the means for generating the plurality of modified fault expressions comprises: means for generating a first fault expression and a second fault expression corresponding to a first fault and a second fault, respectively; means for determining that there exists in the circuit at least an output whose value is to remain incorrect for at least a threshold period of time, if the first fault is assumed to occur; means for determining that there does not exist in the circuit any output whose value is to remain incorrect for at least the threshold period of time, if the second fault is assumed to occur; means for generating, for the first fault, a first modified fault expression to be equal to the first fault expression; means for generating, for the second fault, a second modified fault expression to be equal to zero; and means for generating the plurality of modified fault expressions to include the first modified fault expression and exclude the second modified fault expression.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. One or more non-transitory computer-readable storage media configured to store instructions that, when executed by a processor included in an apparatus, cause the processor to perform operations comprising:
identify a plurality of transition faults that is to possibly occur in a circuit;
generate a plurality of modified fault expressions, at least one of the plurality of modified fault expressions being associated with a corresponding transition fault of the plurality of transition faults;
identify a plurality of test patterns, wherein at least one of the plurality of test patterns is to result in satisfiability of corresponding one or more of the plurality of modified fault expressions; and
output the plurality of test patterns to a testing arrangement to test the circuit.

2. The one or more non-transitory computer-readable storage media of claim 1, wherein:
a test pattern is to result in satisfiability of a modified fault expression if, for the test pattern, the modified fault expression is to evaluate to a logical one value.

3. The one or more non-transitory computer-readable storage media of claim 1, wherein:
the plurality of transition faults comprises one or more slow-to-rise faults and one or more slow-to-fall faults.

4. The one or more non-transitory computer-readable storage media of claim 1, wherein:
the plurality of transition faults comprises a corresponding slow-to-rise fault and a corresponding slow-to-fall fault at a corresponding node of a plurality of nodes of the circuit.

5. The one or more non-transitory computer-readable storage media of claim 1, wherein to identify the plurality of test patterns, the processor is to perform operations comprising:
iteratively identify, using a MAXSAT-BAPA SMT (Maximum Satisfiability-Boolean Algebra Presburger Arithmetic-Satisfiability Modulo Theory) solver, the plurality of test patterns.

6. The one or more non-transitory computer-readable storage media of claim 1, wherein to identify the plurality of test patterns, the processor is to perform operations comprising:
generate a set comprising the plurality of modified fault expressions;
identify, during a first iteration, a first test pattern that satisfies a first number of modified fault expressions of the set; and
update the set by removing the first number of modified fault expressions from the set.

7. The one or more non-transitory computer-readable storage media of claim 6, wherein to identify the plurality of test patterns, the processor is to perform operations comprising:
identify, during a second iteration, a second test pattern that satisfies a second number of modified fault expressions of the updated set;
further update the set by removing the second number of modified fault expressions from the updated set; and
identify the plurality of test patterns such that the plurality of test patterns includes at least the first test pattern and the second test pattern.

8. The one or more non-transitory computer-readable storage media of claim 1, wherein to generate the plurality of modified fault expressions, the processor is to perform operations comprising:
generate a first fault expression and a second fault expression corresponding to a first fault and a second fault, respectively;
determine that there exists in the circuit at least an output whose value is to remain incorrect for at least a threshold period of time, if the first fault is assumed to occur;
determine that there does not exist in the circuit any output whose value is to remain incorrect for at least the threshold period of time, if the second fault is assumed to occur;
generate, for the first fault, a first modified fault expression to be equal to the first fault expression;
generate, for the second fault, a second modified fault expression to be equal to zero; and
generate the plurality of modified fault expressions to include the first modified fault expression and exclude the second modified fault expression.

9. A system comprising:
a testing arrangement to receive a Device Under Test (DUT), and to test the DUT; and
a computing environment coupled to the testing arrangement, the computing environment comprising:
a memory to store instructions; and
a processor coupled to the memory, the processor to:
identify a plurality of transition faults that is to possibly occur in the DUT;
generate a set comprising a plurality of modified fault expressions, at least one of the plurality of modified fault expressions being associated with a corresponding transition fault of the plurality of transition faults;
identify, during a first iteration, a first test pattern that is to satisfy a first number of modified fault expressions of the set, and
update the set, by removing the first number of modified fault expressions from the set, to generate a first updated set.

10. The system of claim 9, wherein the processor is to:
identify, during a second iteration, a second test pattern that is to satisfy a second number of modified fault expressions of the first updated set; and
update the first updated set, by removing the second number of modified fault expressions, to generate a second update set.

11. The system of claim 10, wherein the processor is to:
fail to identify, during a third iteration, any test pattern that satisfies any modified fault expression of the second updated set; and
generate a set of test patterns, the set of test patterns comprising the first test pattern and the second test pattern.

12. The system of claim 11, wherein the processor is to:
transmit the set of test patterns to the testing arrangement.

13. The system of claim 11, wherein the processor is to fail to identify, during the third iteration, any test pattern that satisfies any modified fault expression of the second updated set, as the second updated set is an empty set.

14. The system of claim 10, wherein during the second iteration, the second test pattern satisfies a maximal number of modified fault expressions of the first updated set.

15. The system of claim 9, wherein to identify, during the first iteration, the first test pattern, the processor is to:
identify the first test pattern using a MAXSAT (Maximum Satisfiability) solver.

16. The system of claim 9, wherein to identify, during the first iteration, the first test pattern, the processor is to:
identify that for the first test pattern, individual ones of the first number of modified fault expressions of the set is to evaluate to a logical one value.

17. The system of claim 9, wherein the plurality of transition faults comprises:
a corresponding slow-to-rise fault and a corresponding slow-to-fall fault at a corresponding node of a plurality of nodes of the DUT.

18. A method comprising:
identifying a plurality of transition faults that can possibly occur in a circuit;
generating a plurality of fault expressions respectively corresponding to the plurality of transition faults;
selecting a first subset of the fault expressions from the plurality of fault expressions, such that for at least one fault expression in the first subset, there exists at least one corresponding output of the circuit that is at an incorrect state for more than a threshold period of time, if the corresponding transition fault is to occur; and
generating a plurality of test patterns for testing the circuit, based at least in part on the first subset of fault expressions.

19. The method of claim 18, further comprising:
determining that for each fault expression in a second subset of fault expressions, there does not exist any corresponding output of the circuit that is at an incorrect state for more than the threshold period of time, if the corresponding transition fault is to occur; and
excluding, from the first subset of fault expressions, any fault expression of the second subset of fault expressions.

20. The method of claim 18, wherein generating the plurality of test patterns comprises:
generating the plurality of test patterns using a MAXSAT (Maximum Satisfiability) solver.

21. An apparatus comprising:
a memory to store instructions; and
a processor coupled to the memory, the processor to perform operations comprising:
identify a plurality of transition faults that can possibly occur in a Device Under Test (DUT);
generate a plurality of fault expressions respectively corresponding to the plurality of transition faults;
select a first subset of the fault expressions from the plurality of fault expressions, such that for at least one fault expression in the first subset, there exists at least one corresponding output of the DUT that is at an incorrect state for more than a threshold period of time, if the corresponding transition fault is to occur;
generate a plurality of test patterns for testing the DUT, based at least in part on the first subset of fault expressions; and
transmit the plurality of test patterns to a tester for testing the DUT

22. The apparatus of claim 21, wherein the processor is to perform operations comprising:
determine that for each fault expression in a second subset of fault expressions, there does not exist any corresponding output of the DUT that is at an incorrect state for more than the threshold period of time, if the corresponding transition fault is to occur; and
exclude, from the first subset of fault expressions, any fault expression of the second subset of fault expressions.

23. The apparatus of claim 21, wherein the processor to perform operations comprising:
generate the plurality of test patterns using a MAXSAT (Maximum Satisfiability) solver.

24. The apparatus of claim 21, further comprising:
a communicating link to interface with the tester.

25. The apparatus of claim 21, wherein the processor is to perform operations comprising:
iteratively generate the plurality of test patterns for testing the DUT, such that the plurality of test patterns is a minimal number of test patterns that can test the plurality of transition faults.
